(19) United States
(12) Patent Application Publication
(10) Pub. No.: US 2021/0100122 A1
(43) Pub. Date: Apr. 1, 2021

(54) ELECTRONIC DEVICE WITH A LIQUID-ACTIVATED SEAL

(71) Applicant: Apple Inc., Cupertino, CA (US)

(72) Inventors: Xuefeng WANG, San Jose, CA (US); SungChang LEE, San Jose, CA (US); Alan AN, Sunnyvale, CA (US); Richard BLANCO, San Francisco, CA (US); Andrew CHEN, Sunnyvale, CA (US); Maxime CHEVRETON, Mountain View, CA (US); Kyle B. CRUZ, Campbell, CA (US); Walton FONG, San Jose, CA (US); Nigel J. FUNGE, Redwood City, CA (US); Ki Myung LEE, Cupertino, CA (US); Cheng-I LIN, Emeryville, CA (US); Kenneth H. MAHAN, San Jose, CA (US); Anya PRASITTHIPAYONG, San Jose, CA (US); Alyssa C. RAMDYAL, Waterdown (CA); Nikhil SHARMA, San Jose, CA (US); Eric SHI, Cupertino, CA (US); Wei Guang WU, Palo Alto, CA (US)

(21) Appl. No.: 16/778,272

(22) Filed: Jan. 31, 2020

Related U.S. Application Data
(60) Provisional application No. 62/906,646, filed on Sep. 26, 2019.

(51) Int. Cl. H05K 5/06; H05K 5/00; H04B 1/3888

(52) U.S. Cl. CPC H05K 5/069; H05K 5/03; H04B 1/3888; H05K 5/0017

(57) ABSTRACT

An electronic device with a sealing layer is disclosed. The sealing layer may include several enhancements designed to improve the overall sealing performance. For instance, the sealing layer may include an adhesive material and several particles embedded in the adhesive material. The embedded particles may include liquid-activated particles that respond to liquid exposure. In some instances, the liquid-activated particles absorb the liquid. Additionally, the liquid-activated particles may expand and fill/cover areas previously occupied by the sealing layer or another structure of the electronic device. Further, the liquid-activated particles may adhere to one or more structures of the electronic device, thereby providing the sealing layer with sealing properties. As a result of the absorption/expansion/adhesion properties of the liquid-activated particles, the electronic device may maintain a specified ingress protection rating even subsequent to some form of breakdown of the sealing layer or damage to the electronic device.

### CROSS-REFERENCE TO RELATED APPLICATION(S)

This application claims the benefit of priority to U.S. Provisional Application No. 62/906,646, filed on Sep. 26, 2019, titled “ELECTRONIC DEVICE WITH A LIQUID-ACTIVATED SEAL,” the disclosures of which are incorporated herein by reference in their entirety.

### FIELD

The following description relates to electronic devices. In particular, the following description relates to electronic devices with a sealing layer that includes embedded particles. The particles are designed to respond to liquid exposure. In some instances, when the particles are exposed to liquid, the particles absorb the liquid, expand, and/or adhere to surrounding structures. As a result, the particles can support the sealing layer by providing a seal against liquid ingress into the electronic devices, particularly when the sealing layer undergoes some form of breakdown.

### BACKGROUND

Electronic devices include multiple parts secured together by adhesives. Based on the type of adhesive used, the electronic device manufacturer may desire to warrant the electronic device as having a particular ingress protection (“IP”) rating. Such a rating conveys to an end user that the electronic device will not undergo damage in certain instances of water exposure.

However, while the electronic device may initially perform in accordance with the IP rating, the liquid ingress performance may degrade over time. For example, the adhesives can wear down due to dropping the electronic device and/or thermal exposure from heat-generating components, such as processing circuitry, within the electronic device. As a result, the electronic device that could once withstand water exposure may no longer be able to do so, and further water exposure may subject the electronic device to damage.

### SUMMARY

In one aspect, an electronic device is described. The electronic device may include a housing that defines a platform. The electronic device may further include a transparent layer carried by a frame. The electronic device may further include a sealing layer that secures the transparent layer with the housing. The sealing layer may include an adhesive material. The sealing layer may further include liquid-activated particles embedded in the adhesive material. In some embodiments, when exposed to a liquid, the liquid-activated particles i) absorb at least some of the liquid, and ii) adhere to at least one of the frame or the housing.

In another aspect, an electronic device is described. The electronic device may include a housing that defines a platform. The electronic device may further include a transparent layer. The electronic device may further include a sealing layer positioned on the platform. The sealing layer may secure the transparent layer with the housing. The electronic device may further include a liquid-activated particle embedded in the sealing layer. In some embodiments, a first state includes the liquid-activated particle having a first size. Further, in some embodiments, a second state includes the liquid-activated particle having a second size greater than the first size.

In another aspect, a method for sealing an electronic device is described. The method may include securing, by a sealing layer, a frame with a housing. The sealing layer may include a liquid-activated particle. The method may further include, when the liquid-activated particle is exposed to a liquid, absorbing, by the liquid-activated particle, at least some of the liquid. The method may further include, when the liquid activated-particle is exposed to a liquid, expanding, by the liquid-activated particle, from a first size to a second size greater than the first size.

Other systems, methods, features and advantages of the embodiments will be, or will become, apparent to one of ordinary skill in the art upon examination of the following figures and detailed description. It is intended that all such additional systems, methods, features and advantages be included within this description and this summary, be within the scope of the embodiments, and be protected by the following claims.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a front isometric view of an embodiment of an electronic device;

FIG. 2 illustrates a rear isometric view the electronic device shown in FIG. 1, showing additional features;

FIG. 3 illustrates an exploded view of the electronic device shown in FIG. 1, showing various structural features of the electronic device, in accordance with some described embodiments;

FIG. 4 illustrates a cross sectional view of the electronic device, showing the sealing layer bonded to the frame and the band;

FIG. 5 illustrates a cross sectional view of the electronic device, showing the sealing layer exposed to liquid;

FIG. 6 illustrates a cross sectional view of the electronic device shown in FIG. 5, showing the particles in the sealing layer activated in response to the exposure to the liquid;

FIG. 7 illustrates a cross sectional view of the electronic device, showing the sealing layer exposed to liquid subsequent to damage to the electronic device;

FIG. 8 illustrates a cross sectional view of the electronic device shown in FIG. 7, showing the particles activated in response to the exposure to the liquid;

FIG. 9A illustrates a cross sectional view of an alternate embodiment of an electronic device, showing a modified sealing layer;

FIG. 9B illustrates a cross sectional view of an alternate embodiment of an electronic device, showing particles embedded in a frame of the electronic device;

FIG. 9C illustrates a cross sectional view of an alternate embodiment of an electronic device, showing a modified sealing layer;

FIG. 10A illustrates a plan view of an alternate embodiment of an electronic device, showing a sealing layer with particles located at the corners of the electronic device;

FIG. 10B illustrates a plan view of an alternate embodiment of an electronic device, showing a sealing layer with particles located along split regions of a band of the electronic device;

FIG. 11 illustrates a flowchart showing a method for sealing an electronic device, in accordance with some described embodiments; and

FIG. 12 illustrates a block diagram of an electronic device, in accordance with some described embodiments.

Those skilled in the art will appreciate and understand that, according to common practice, various features of the drawings discussed below are not necessarily drawn to scale, and that dimensions of various features and elements of the drawings may be expanded or reduced to more clearly illustrate the embodiments of the present invention described herein.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting such that other embodiments may be used, and changes may be made without departing from the spirit and scope of the described embodiments.

The following disclosure relates to electronic devices that provide an enhanced liquid ingress barrier. Electronic devices described herein may refer to portable electronic devices (such as smartphones and tablet computing devices) and wearable electronic devices (such as a smart watch), as non-limiting examples. An electronic device described herein may include a sealing layer that secures together two or more components. In this regard, the sealing layer may include an adhesive material that also acts as a sealing layer to prevent liquid ingress into the electronic device.

In addition, the sealing layer may include a hybrid structure that includes not only an adhesive material by also liquid-activated particles, or elements, embedded in the adhesive material. As an example, the material that forms the liquid-activated particles may include rubber. Further, the material that forms the liquid-activated particles may include hydrophilic rubber. While the adhesive material may provide the primary sealing and ingress protection features, the liquid-activated elements may also provide sealing and ingress functionality. For example, when the electronic device is exposed to water, the water may enter a gap between the components secured together by the sealing layer. When the water comes into contact with the liquid-activated elements, the liquid-activated elements may respond by absorbing the water, causing a reduction in the water through a chemical reaction, as a non-limiting example.

Further, in some instances, the liquid-activated particles may respond to water exposure by expanding. In this regard, the liquid-activated particles may swell when exposed to water. The expansion can provide additional benefits. For example, the expansion by the liquid-activated particles can occupy a space (or spaces) previously occupied by the sealing layer when the sealing layer undergoes some form of breakdown. Additionally, should a structural component, or components, within the vicinity of the sealing layer become damaged, the expansion by the liquid-activated particles can fill and cover the damaged area of the structural component. For instance, the electronic device may include a plastic frame susceptible to cracking, and if water enters the crack and reaches the sealing layer, the liquid-activated particles can fill and cover the crack(s).

Even further, in some instances, the liquid-activated particles may respond to water exposure by adhering to surrounding structures. As an example, the electronic device may include a housing, or an enclosure, and a transparent layer (e.g., cover glass) that is held by the plastic frame. The sealing layer may secure the plastic frame with the housing. When the liquid-activated particles are exposed to water, the liquid-activated particles may engage and adhere to the plastic frame and/or the housing, in addition to providing the water absorption and expansion features. As a result, both the adhesive material and the liquid-activated particles of the sealing layer provide sealing properties.

Based on the foregoing benefits, the hybrid sealing layer described herein provides sealing capabilities even when some undesired modification occurs to the electronic device, such as a partial breakdown of the sealing layer or damage to the electronic device. As a result of the benefits of the hybrid sealing layer described herein, the electronic device may maintain an ingress protection (“IP”) specification even when the electronic device undergoes the undesired modification.

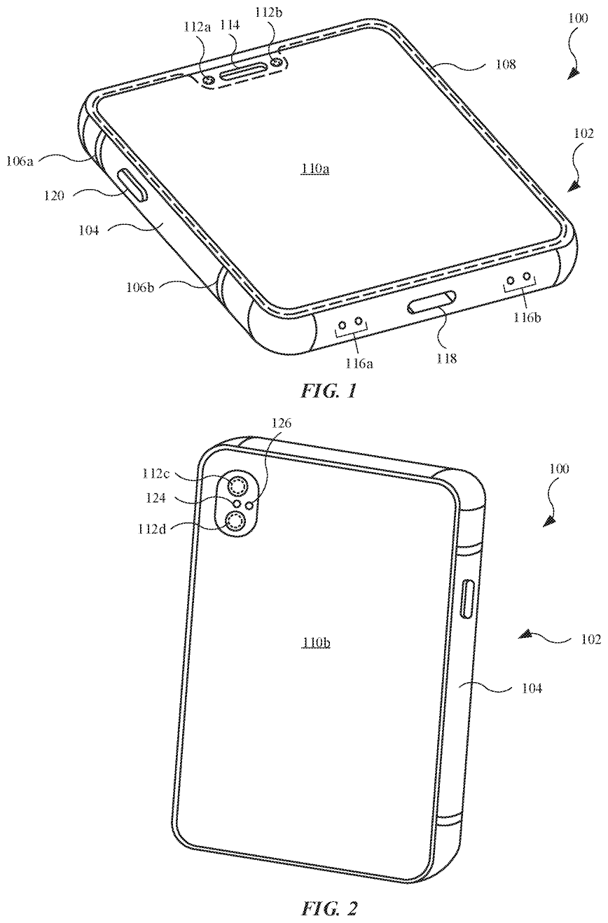

These and other embodiments are discussed below with reference to FIGS. 1-12. However, those skilled in the art will readily appreciate that the detailed description given herein with respect to these Figures is for explanatory purposes only and should not be construed as limiting.

FIG. 1 illustrates a front isometric view of an embodiment of an electronic device 100. In some embodiments, the electronic device 100 is a wearable electronic device, such as a smart watch. In the embodiment shown in FIG. 1, the electronic device 100 is a mobile wireless communication device, such as a smart phone or a tablet computing device.

As shown, the electronic device 100 may include a housing 102, or enclosure. The housing 102 can define an internal volume designed to carry several components, such as processing circuitry (including central processing units and graphics processing units), memory circuitry, batteries, camera modules, and flexible circuitry that connects together the components, as non-limiting examples. The housing 102 may include a band 104, or ring, that defines in part an outer perimeter of the electronic device 100. In some embodiments, the band 104 is formed from a metal such as stainless steel or aluminum. As a result, in order to promote wireless communication (such as cellular, BLUETOOTH®, or WI-FI® communication), the band 104 may include several split regions filled with a non-metal material. For example, the band 104 may include a non-metal material 106a and a non-metal material 106b, each filling a split region of the band 104. The non-metal material 106a and the non-metal material 106b may include plastic, resin, and/or adhesive, as non-limiting examples. Accordingly, radio frequency communication is permitted through these non-metal materials. Also, the band 104 can combine with a back wall defined by a transparent cover (not shown in FIG. 1) to define the housing 102.

The electronic device 100 may further include a display assembly 108 (shown as a dotted line). The display assembly 108 may include a touchscreen display having a capacitive touch input layer and a display layer configured to present visual information in the form of still images, motion images, and textual information. The electronic device 100 may further include a transparent layer 110a that covers the display assembly 108, and the display assembly 108 may be adhered to the transparent layer 110a such that the display assembly 108 is suspended from the transparent layer 110a. The transparent layer 110a, also referred to as a cover glass, may include generally any transparent material including glass, plastic, or sapphire.

The electronic device 100 may further include an image capture module 112a and an image capture module 112b. The image capture modules may take the form of camera modules, light-emitting modules, or light-receiving modules. Also, the transparent layer 110a may include an opening 114 for an audio module (not shown in FIG. 1), such as a speaker module, located in the internal volume. The electronic device 100 may further include openings 116a and openings 116b used as acoustical pathways for internal components, such as audio modules including a speaker module and a microphone. The electronic device 100 may further include a port 118 designed to receive a connector (not shown in FIG. 1) used to provide power and/or data transmission to the electronic device 100. The electronic device 100 may further include a button 120 that can be actuated to provide an input or command to processing circuitry of the electronic device 100.

FIG. 2 illustrates a rear isometric view the electronic device 100 shown in FIG. 1, showing additional features. The electronic device 100 may include a transparent layer 110b that may be formed from any material described for the transparent layer 110a (shown in FIG. 1). The band 104 and the transparent layer 110b can combine to form the housing 102. The transparent layer 110b may include an opening to accommodate additional components. For example, the electronic device 100 may include an image capture module 112c and an image capture module 112d separated from the image capture module 112c by a flash module 124. The modules may be positioned at a location corresponding to the opening in the transparent layer 110b. The image capture module 112c and an image capture module 112d may include any feature(s) described for the image capture module 112a and an image capture module 112b (shown in FIG. 1). The flash module 124 may include a strobe module that provides additional light during image capturing events by the image capture module 112c and/or the image capture module 112d. Also, the electronic device 100 may include a microphone 126.

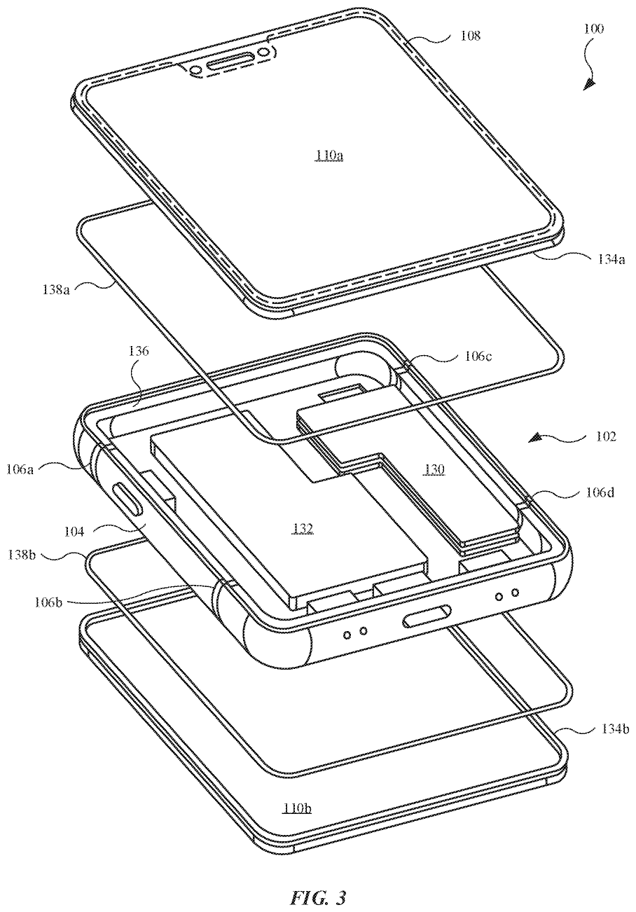

FIG. 3 illustrates an exploded view of the electronic device 100 shown in FIG. 1, showing various structural features of the electronic device 100, in accordance with some described embodiments. As shown, the electronic device 100 includes an internal volume (defined by the housing 102) that carries a circuit board assembly 130 and a battery 132 (or power supply). For purposes of illustration and simplicity, several internal components are removed. Also, in additional to the non-metal material 106a and the non-metal material 106b, the band 104 may further include a non-metal material 106c and a non-metal material 106d.

The electronic device 100 further includes a frame 134a that is coupled to the transparent layer 110a, as well as a frame 134b that is coupled to the transparent layer 110b. Further, a platform 136 is formed into the band 104 to receive the frame 134a (as well as the transparent layer 110a and the display assembly 108 that are coupled with the frame 134a). In order to secure the frame 134a with the platform 136, the electronic device 100 includes a sealing layer 138a that adheres or bonds to both the frame 134a and the band 104 (including the non-metal materials) at the platform 136. The electronic device 100 further includes a sealing layer 138b that adheres or bonds to both the frame 134b and the band 104 (including the non-metal materials) at an additional platform (not shown in FIG. 3) formed into the band 104. Accordingly, the sealing layer 138a and the sealing layer 138b can secure the frame 134a and the frame 134b, respectively, with the band 104. Also, similar to the band 104, the sealing layer 138a and the sealing layer 138b may each define a ring.

In some embodiments, the sealing layer 138a and the sealing layer 138b include an adhesive such as a pressure-sensitive adhesive (“PSA”), as a non-limiting example, that activates in response to an applied pressure. In addition to providing adhesion properties, the sealing layer 138a and the sealing layer 138b may provide ingress protection and act as a barrier against liquid exposure to the electronic device 100, thereby protecting sensitive components in the electronic device 100. In this regard, the sealing layer 138a and the sealing layer 138b may include modifications. For example, the sealing layer 138a and the sealing layer 138b may each include liquid-activated particles (not shown in FIG. 3) designed to enhance sealing properties of their respective sealing layers. This will be shown and described below.

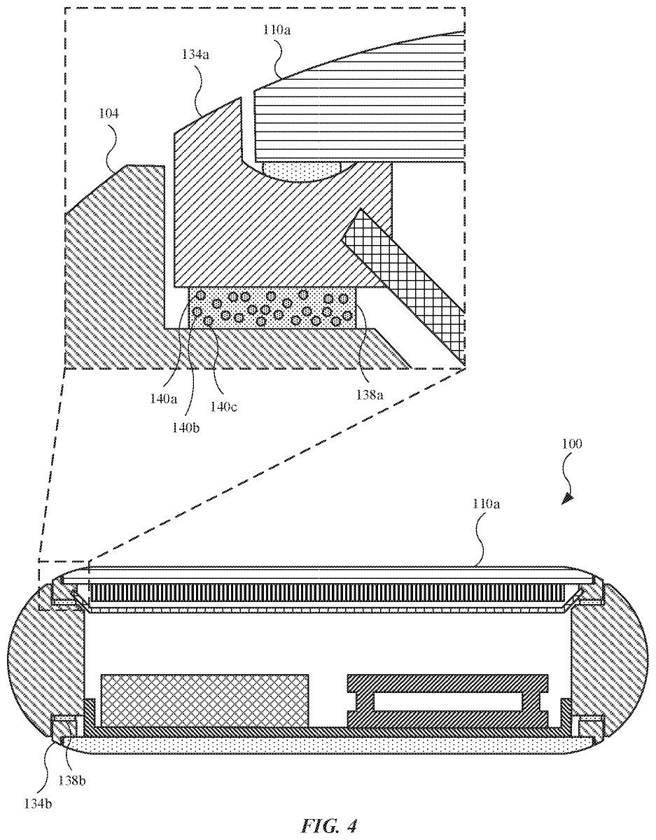

FIG. 4 illustrates a cross sectional view of the electronic device 100, showing the sealing layer 138a bonded to the frame 134a and the band 104. As shown in the enlarged view, the sealing layer 138a includes several embedded particles, such as a particle 140a, a particle 140b, and a particle 140c. These particles are representative of the remaining particles in the sealing layer 138a. Each particle in the sealing layer 138a may include a generally spherical material with a diameter approximately in the range of 100-500 micrometers. However, the shape may vary. It should be noted that the size of the particles shown in FIG. 4 are exaggerated for purposes of illustration. The particles may include liquid-activated particles designed to respond to liquid exposure. Although not shown, the sealing layer 138b—used to bond the frame 134b with the band 104—may include embedded particles with the same or similar properties as those in the sealing layer 138a.

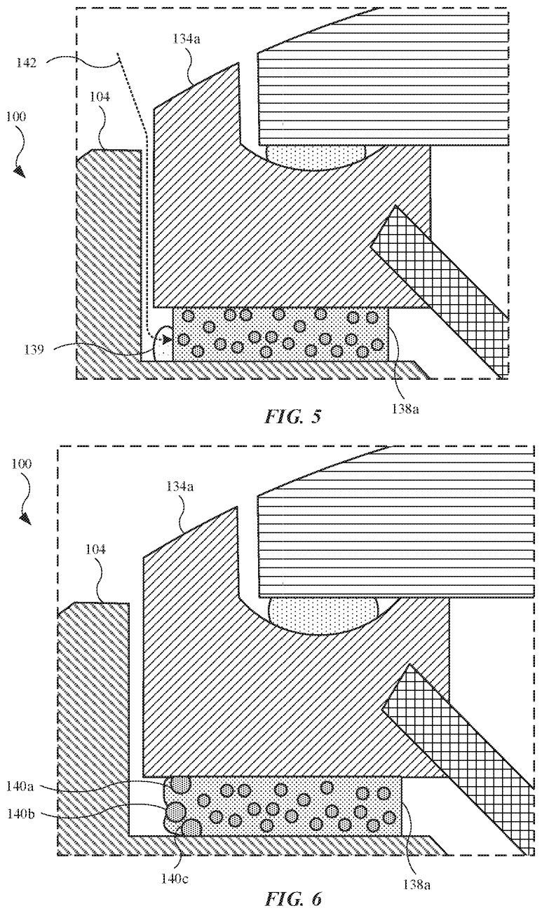

FIG. 5 illustrates a cross sectional view of the electronic device 100, showing the sealing layer 138a exposed to liquid 139. The liquid 139 may include water or an aqueous-based solution. As shown, liquid ingress (represented by the dotted line 142) may occur between the band 104 and the frame 134a, causing liquid exposure to the sealing layer 138a. While the sealing layer 138a can act as a barrier to any further liquid ingress, in some instances, the sealing layer 138a may undergo breakdown over time due in part to dropping the electronic device 100 or by thermal exposure from heat-generating components (e.g., processing circuitry, battery) of the electronic device 100. However, the embedded particles may provide support against liquid ingress.

FIG. 6 illustrates a cross sectional view of the electronic device 100 shown in FIG. 5, showing the particles in the sealing layer 138a activated in response to the exposure to the liquid. In order to reduce the volume of the liquid, the particles may absorb the liquid. For example, the particle 140a, the particle 140b, and the particle 140c (generally located at the edge of the sealing layer 138a) absorb at least some of the liquid that passes between the band 104 and the frame 134a. The absorption may result from a chemical reaction between the liquid and the particles, as a non-limiting example.

Further, due in part to the liquid exposure, the particles in the sealing layer 138a may change in size. For example, the particle 140a, the particle 140b, and the particle 140c may respond to the liquid exposure by expanding. The expansion may cause the particle 140a, the particle 140b, and/or the particle 140c to fill in voids or spaces left due to breakdown of the sealing layer 138a. For example, the particle 140b occupies a portion of the space previously occupied by the sealing layer 138a.

Further, the particles may include adhesion properties that cause the particles to bond or adhere to a structure(s) of the electronic device 100. For example, the particle 140a is bonded to the frame 134a and the particle 140c is bonded to the band 104. As a result, the particle 140a, and the particle 140c may provide at least some ingress protection against liquid. The bonding of the particle 140a and the particle 140c to the frame 134a and the band 104, respectively, indicate the particles can bond not only to different surfaces of different structures, but can also bond to structures of different material makeup, as the frame 134a may include plastic while the band 104 may include a metal.

Prior to liquid exposure, the particles may be defined by a first, or initial, state. After liquid exposure, however, the particles may transition to from the first state to a second, or subsequent, state. FIG. 5 represents particles embedded in the sealing layer 138a in the first state, while FIG. 6 represents particles embedded in the sealing layer 138a in the second state. Also, while the transformation shown and described for the particles in FIG. 6 applies to a select number of particles, any particle embedded in the sealing layer 138a may undergo similar transformations as those exemplified by the particle 140a, the particle 140b, and the particle 140c. Further, the sealing layer 138b (shown in FIG. 4) may include embedded particles that can undergo the same or similar transformations as those embedded in the sealing layer 138a.

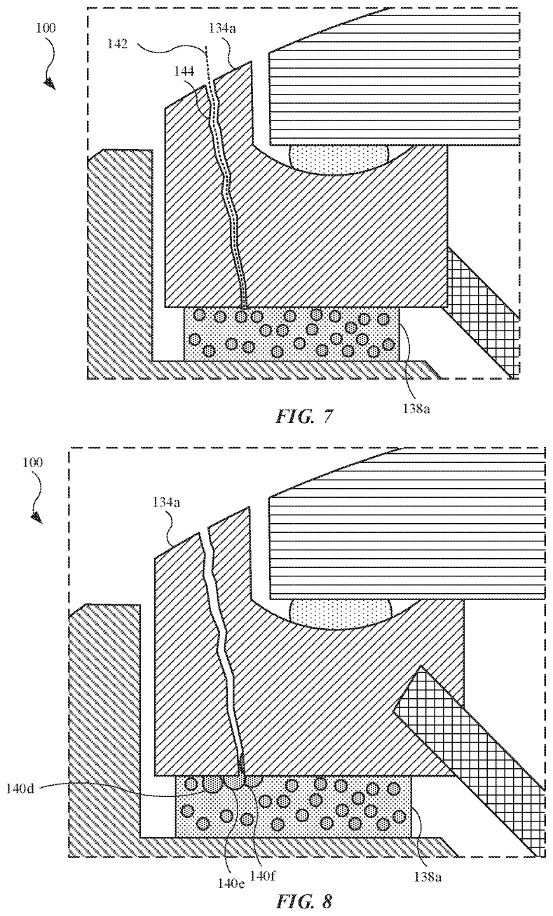

In addition to supporting the sealing layer 138a, the particles are also designed to provide ingress protection when damage occurs to electronic device 100. For example, FIG. 7 illustrates a cross sectional view of the electronic device 100, showing the sealing layer 138a exposed to liquid subsequent to damage to the electronic device 100. As shown, the frame 134a includes a damaged region 144 defined by a crack that extends through the frame 134a and to the sealing layer 138a. In some instances, when the electronic device 100 is exposed to liquid, the liquid (represented by the dotted line 142) passes through the damaged region 144, causing liquid exposure to the sealing layer 138a. However, the embedded particles may again provide support against liquid ingress.

FIG. 8 illustrates a cross sectional view of the electronic device shown in FIG. 7, showing the particles activated in response to the exposure to the liquid. As shown, the sealing layer 138a includes a particle 140d, a particle 140e, and a particle 140f (representative of additional particles) that absorb at least some of the liquid and expand. In order to reduce the volume of the liquid, the particle 140d, the particle 140e, and the particle 140f may absorb the liquid. Further, the particle 140d, the particle 140e, and the particle 140f may include adhesion properties that cause the particles to bond or adhere to the frame 134a including the surfaces of the damaged region 144. For example, the particle 140d the is bonded to the frame 134a, while the particle 140e and the particle 140f are bonded to surfaces defined by the damaged region 144.

While the transformation shown and described for the particles in FIG. 8 applies to a select number of particles, any particle embedded in the sealing layer 138a may undergo similar transformations as those exemplified by the particle 140d, the particle 140e, and the particle 140f. Further, the sealing layer 138b (shown in FIG. 4) may include embedded particles that can undergo similar transformations as those embedded in the sealing layer 138a.

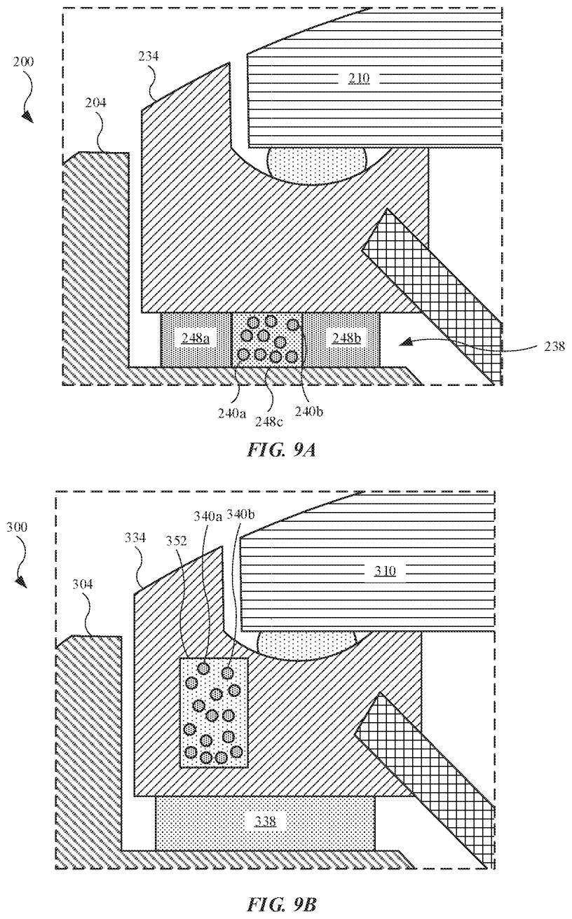

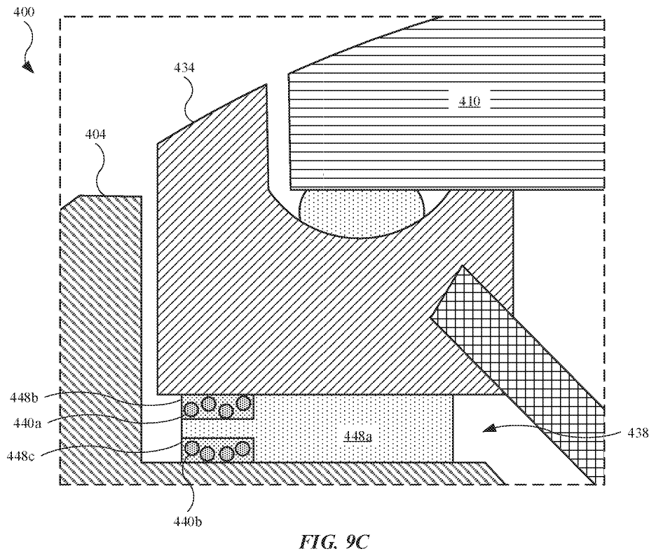

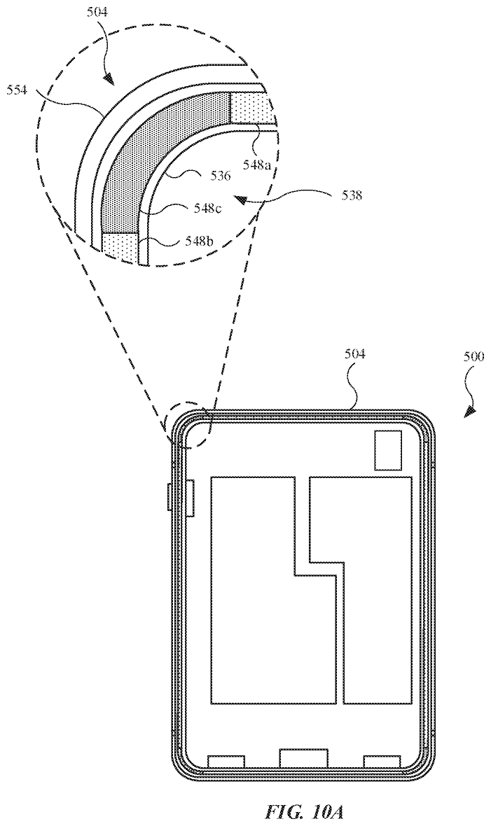

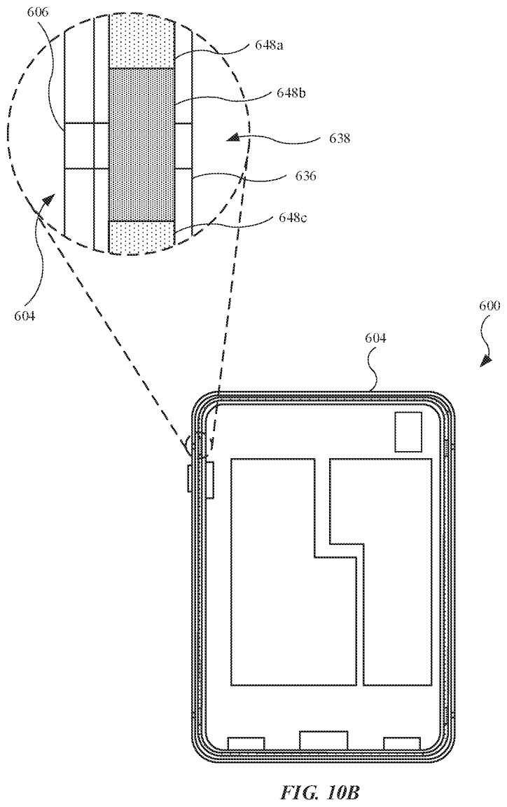

FIGS. 9A-10B show and described additional embodiments of electronic devices with various modifications to their respective sealing layers. The electronic devices shown and described in FIGS. 9A-10B may include features described herein for the electronic device 100 (shown in FIGS. 1-8), including the sealing layer 138a and the sealing layer 138b of the electronic device 100.

FIG. 9A illustrates a cross sectional view of an alternate embodiment of an electronic device 200, showing a modified sealing layer. As shown, the electronic device 200 includes a band 204 and a frame 234 (carrying a transparent layer 210) that is secured with the band 204 by a sealing layer 238. The sealing layer 238 may include an assembly of features. For example, the sealing layer 238 may include an adhesive section 248a, an adhesive section 248b, and an adhesive section 248c. The adhesive section 248a, the adhesive section 248b, and the adhesive section 248c may be referred to as a first adhesive section, a second adhesive section, and a third adhesive section, respectively.

The adhesive section 248a and the adhesive section 248b may be substantially defined by an adhesive, such as PSA (as a non-limiting example), that includes no participles. However, the adhesive section 248c (located between the adhesive section 248a and the adhesive section 248b) may include a combination of an adhesive plus particles. The particles, such as a particle 240a and a particle 240b (representative of the remaining particles), may include liquid-activated particles that provide features such as absorption and expansion in response to liquid exposure, as well as adhesion to the band 204 or the frame 234. As a result, the sealing layer 238 may include increased bonding strength due in part to the adhesive section 248a and the adhesive section 248b, while also providing support against liquid ingress by the particles in the adhesive section 248c, should the particles be exposed to liquid.

FIG. 9B illustrates a cross sectional view of an alternate embodiment of an electronic device 300, showing particles embedded in a frame 334 of the electronic device 300. As shown, frame 334 (carrying a transparent layer 310) is secured with a band 304 of the electronic device 300 by a sealing layer 338. The sealing layer 338 may substantially be defined by an adhesive, such as PSA (as a non-limiting example). However, the sealing layer 338 may be modified to include any features previously described for a sealing layer.

The frame 334 may include a compound 352 embedded in the frame 334. The compound 352 may be integrated with the frame 334 during a molding operation of the frame 334, as a non-limiting example. As shown, the compound 352 includes several embedded particles. For instance, the compound 352 may include particles, such as a particle 340a and a particle 340b (representative of the remaining particles), that define liquid-activated particles that provide features such as absorption and expansion in response to liquid exposure. This may occur if the frame 334 becomes damaged and liquid reaches the compound 352. Further, the particles, when exposed to liquid, may adhere to the frame 334. As a result, the compound 352, using the liquid-activated particles, may support ingress protection if the frame 334 undergoes breakdown.

FIG. 9C illustrates a cross sectional view of an alternate embodiment of an electronic device 400, showing a modified sealing layer. As shown, the electronic device 400 includes a band 404 and a frame 434 (carrying a transparent layer 410) that is secured with the band 404 by a sealing layer 438. The sealing layer 438 may include an assembly of features. For example, the sealing layer 438 may include an adhesive section 448a, an adhesive section 448b, and an adhesive section 448c. The adhesive section 448a, the adhesive section 448b, and the adhesive section 448c may be referred to as a first adhesive section, a second adhesive section, and a third adhesive section, respectively.

The adhesive section 448a may be substantially defined by an adhesive, such as PSA (as a non-limiting example), that includes no participles. However, the adhesive section 448b and the adhesive section 448c may each include a combination of an adhesive plus particles. The particles, such as a particle 440a and a particle 440b (representative of the remaining particles) located in the adhesive section 448a and the adhesive section 448c, respectively, may include liquid-activated particles that provide features such as absorption and expansion in response to liquid exposure.

As shown, the adhesive section 448b and the adhesive section 448c are positioned in a location that may be subject to liquid ingress, i.e., in a gap between the band 404 and the frame 434. In the event of liquid exposure, the liquid-activated particles in the adhesive section 448b are positioned to adhere to the frame 434, while the liquid-activated particles in the adhesive section 448c are positioned to adhere to the band 404. As a result, the sealing layer 438 may include increased bonding strength due in part to the adhesive section 448a, while also providing support against liquid ingress by the particles in the adhesive section 448b and the adhesive section 448c.

While the prior embodiments show and describe sealing layers with a cross section generally representative of the remaining regions of the sealing layer, the sealing layers shown and described in FIGS. 10A and 10B may include a combination of adhesive sections with and without liquid-activated particles. Also, for purposes of illustration, the transparent layer and frame are removed in the embodiments shown in FIGS. 10A and 10B.

FIG. 10A illustrates a plan view of an alternate embodiment of an electronic device 500, showing a sealing layer 538 with particles located at the corners of the electronic device. The electronic device 500 may include a band 504. As shown in the enlarged view, the band 504 includes a corner 554. Further, the sealing layer 538 is located on a platform 536 of the band 504. The sealing layer 538 may include an adhesive section 548a, an adhesive section 548b, and an adhesive section 548c. The adhesive section 548a, the adhesive section 548b, and the adhesive section 548c may be referred to as a first adhesive section, a second adhesive section, and a third adhesive section, respectively. Also, the adhesive section 548a and the adhesive section 548b generally cover the “straight away,” or linear, regions of the platform 536, while the adhesive section 548c covers the corners, such as the corner 554.

The adhesive section 548a and the adhesive section 548b may be substantially defined by an adhesive, such as PSA (as a non-limiting example), that includes no participles. However, the adhesive section 548c (located between the adhesive section 548a and the adhesive section 548b) may include a combination of an adhesive plus particles. The particles (not labeled) may include liquid-activated particles that provide features such as absorption and expansion in response to liquid exposure, as well as adhesion to the band 504 or the frame (not shown in FIG. 10A). As a result, the sealing layer 538 may include increased bonding strength due in part to the adhesive section 548a and the adhesive section 548b, while also providing support against liquid ingress by the particles in the adhesive section 548c, particularly in a location—the corner 554—more likely to absorb shock during a drop event of the electronic device 500. Also, while an application of the sealing layer 538 is shown and described for the corner 554, the remaining corners of the electronic device 500 may be covered by the sealing layer 538 in a manner similar to that of the corner 554.

FIG. 10B illustrates a plan view of an alternate embodiment of an electronic device 600, showing a sealing layer 638 with particles located along split regions of a band 604 of the electronic device 600. As shown in the enlarged view, the band 604 includes a non-metal material 606 located in a split region of the band 604. Further, the sealing layer 638 is located on a platform 636 of the band 604. The sealing layer 638 may include an adhesive section 648a, an adhesive section 648b, and an adhesive section 648c. The adhesive section 648a, the adhesive section 648b, and the adhesive section 648c may be referred to as a first adhesive section, a second adhesive section, and a third adhesive section, respectively. Also, the adhesive section 648a and the adhesive section 648b generally cover the “straight away,” or linear, regions and the corners of the platform 636, while the adhesive section 648c covers the non-metal material 606.

The adhesive section 648a and the adhesive section 648b may be substantially defined by an adhesive, such as PSA (as a non-limiting example), that includes no participles. However, the adhesive section 648c (located between the adhesive section 648a and the adhesive section 648b) may include a combination of an adhesive plus particles. The particles (not labeled) may include liquid-activated particles that provide features such as absorption and expansion in response to liquid exposure, as well as adhesion to the band 604 or the frame (not shown in FIG. 10B). As a result, the sealing layer 638 may include increased bonding strength due in part to the adhesive section 648a and the adhesive section 648b, while also providing support against liquid ingress by the particles in the adhesive section 648c, particularly in a location—the non-metal material 606—more likely to delaminate from the band 604 during a drop event of the electronic device 600. Also, while an application of the sealing layer 638 is shown and described for the non-metal material 606, the remaining non-metal materials of the electronic device 600 may be covered by the sealing layer 638 in a manner similar to that of the non-metal material 606.

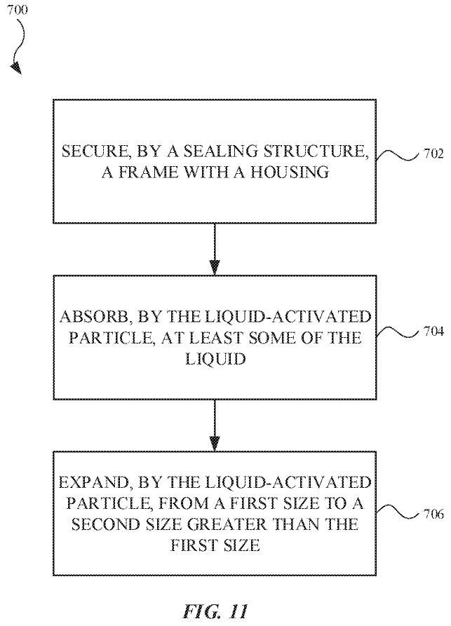

FIG. 11 illustrates a flowchart 700 showing a method for sealing an electronic device, in accordance with some described embodiments. The flowchart 700 may describe in part a method or process to form electronic devices described herein.

At step 702, a sealing layer is used to secure a frame with a housing. The sealing layer may include a liquid-activated particle. The liquid-activated particle may be one of several liquid-activated particles embedded in the sealing layer. The liquid-activated particle may include a material, such as hydrophilic rubber. Also, the liquid-activated particle may include a spherical shape. However, the shape may vary.

The liquid-activated particle is designed to react to liquid. For example, at step 704, when the liquid-activated particle is exposed to the liquid, the liquid-activated particle absorbs at least some of the liquid to which the liquid-activated particle is exposed. This absorption may be performed by, for example, a chemical reaction.

At step 706, the liquid-activated particle, when exposed to the liquid, expands from a first size to a second size greater than the first size. This may cause the liquid-activated particle to fill in location previously occupied by the sealing layer and/or by a structural component of the electronic device. Additionally, the liquid-activated particle may bond or adhere to a component of the electronic device, such as a frame or a band.

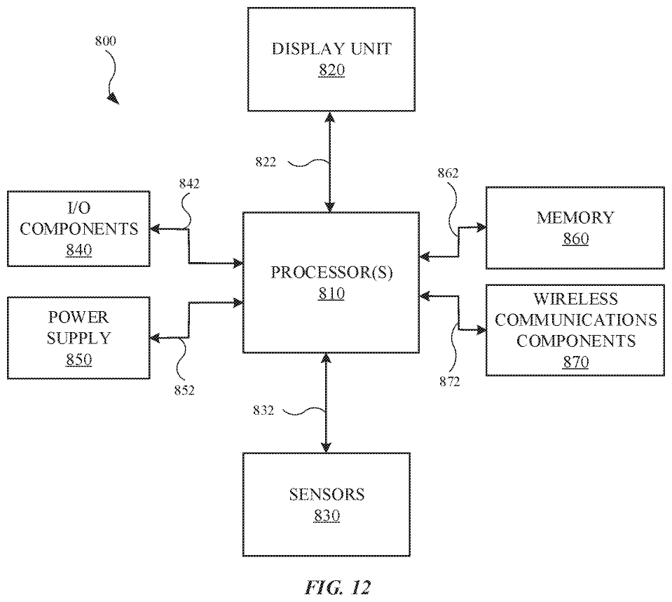

FIG. 12 illustrates a block diagram of an electronic device, in accordance with some described embodiments. The features in the electronic device 800 may be present in other electronic devices described herein. The electronic device 800 may include one or more processors 810 for executing functions of the electronic device 800. The one or more processors 810 can refer to at least one of a central processing unit (CPU) and at least one microcontroller for performing dedicated functions. Also, the one or more processors 810 can refer to application specific integrated circuits.

According to some embodiments, the electronic device 800 can optionally include a display unit 820. The display unit 820 is capable of presenting a user interface that includes icons (representing software applications), textual images, and/or motion images. In some examples, each icon can be associated with a respective function that can be executed by the one or more processors 810. In some cases, the display unit 820 includes a display layer (not illustrated), which can include a liquid-crystal display (LCD), light-emitting diode display (LED), or the like. According to some embodiments, the display unit 820 includes a touch input detection component and/or a force detection component that can be configured to detect changes in an electrical parameter (e.g., electrical capacitance value) when the user's appendage (acting as a capacitor) comes into proximity with the display unit 820 (or in contact with a transparent layer that covers the display unit 820). The display unit 820 is connected to the one or more processors 810 via one or more connection cables 822.

According to some embodiments, the electronic device 800 can include one or more sensors 830 capable of provide an input to the one or more processors 810 of the electronic device 800. The one or more sensors 830 may include a temperature sensor, as a non-limiting example. The one or more sensors 830 is/are connected to the one or more processors 810 via one or more connection cables 832.

According to some embodiments, the electronic device 800 can include one or more input/output components 840. In some cases, the one or more input/output components 840 can refer to a button or a switch that is capable of actuation by the user. When the one or more input/output components 840 are used, the one or more input/output components 840 can generate an electrical signal that is provided to the one or more processors 810 via one or more connection cables 842.

According to some embodiments, the electronic device 800 can include a power supply 850 that is capable of providing energy to the operational components of the electronic device 800. In some examples, the power supply 850 can refer to a rechargeable battery. The power supply 850 can be connected to the one or more processors 810 via one or more connection cables 852. The power supply 850 can be directly connected to other devices of the electronic device 800, such as the one or more input/output components 840. In some examples, the electronic device 800 can receive power from another power sources (e.g., an external charging device) not shown in FIG. 12.

According to some embodiments, the electronic device 800 can include memory 860, which can include a single disk or multiple disks (e.g., hard drives), and includes a storage management module that manages one or more partitions within the memory 860. In some cases, the memory 860 can include flash memory, semiconductor (solid state) memory or the like. The memory 860 can also include a Random Access Memory (“RAM”) and a Read-Only Memory (“ROM”). The ROM can store programs, utilities or processes to be executed in a non-volatile manner. The RAM can provide volatile data storage, and stores instructions related to the operation of the electronic device 800. In some embodiments, the memory 860 refers to a non-transitory computer readable medium. The one or more processors 810 can also be used to execute software applications. In some embodiments, a data bus 862 can facilitate data transfer between the memory 860 and the one or more processors 810.

According to some embodiments, the electronic device 800 can include wireless communications components 870. A network/bus interface 872 can couple the wireless communications components 870 to the one or more processors 810. The wireless communications components 870 can communicate with other electronic devices via any number of wireless communication protocols, including at least one of a global network (e.g., the Internet), a wide area network, a local area network, a wireless personal area network (WPAN), or the like. In some examples, the wireless communications components 870 can communicate using NFC protocol, BLUETOOTH® protocol, or WIFI® protocol.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An electronic device, comprising:
a housing that defines a platform;
a transparent layer carried by a frame; and
a sealing layer that secures the transparent layer with the housing, the sealing layer comprising:
an adhesive material, and
liquid-activated particles embedded in the adhesive material, wherein when exposed to a liquid, the liquid-activated particles i) absorb at least some of the liquid, and ii) adhere to at least one of the frame or the housing.

2. The electronic device of claim 1, wherein the liquid-activated particles comprise a particle such that, when exposed to the liquid, expand from a first size to a second size greater than the second size, wherein the particle, at the second size occupies a location previously occupied by the adhesive material.

3. The electronic device of claim 1, wherein the liquid-activated particles each comprise a spherical material that includes hydrophilic rubber.

4. The electronic device of claim 1, wherein the liquid-activated particles define a seal at the housing when adhered to the frame.

5. The electronic device of claim 1, wherein the liquid-activated particles define a seal at the housing when adhered to the housing.

6. The electronic device of claim 1, further comprising a compound embedded in the frame, the compound comprising a second liquid-activated particle that, when exposed to the liquid, is configured to i) absorb the liquid, ii) expand from a first size to a second size, and iii) adhere to at least one of the frame or the housing.

7. The electronic device of claim 1, wherein the sealing layer defines a ring.

8. An electronic device, comprising:
a housing that defines a platform;
a transparent layer;
a sealing layer positioned on the platform, the sealing layer securing the transparent layer with the housing; and
a liquid-activated particle embedded in the sealing layer, wherein:
a first state comprises the liquid-activated particle having a first size, and
a second state comprises the liquid-activated particle having a second size greater than the first size.

9. The electronic device of claim 8, wherein the liquid-activated particle transitions from the first state to the second state when exposed to a liquid.

10. The electronic device of claim 9, wherein the second state comprises the liquid-activated particle absorbing the liquid.

11. The electronic device of claim 9, wherein the second state comprises the liquid-activated particle adhering to the housing at the platform.

12. The electronic device of claim 9, further comprising a frame that carries the transparent layer, wherein the second state comprises the liquid-activated particle adhering to the frame.

13. The electronic device of claim 8, wherein the liquid-activated particle comprises a hydrophilic rubber.

14. The electronic device of claim 8, wherein the sealing layer comprises:
a first adhesive section;
a second adhesive section; and
a third adhesive section that separates the first adhesive section from the second adhesive section, wherein the liquid-activated particle is located in the third adhesive section.

15. The electronic device of claim 8, further comprising a display assembly suspended from the transparent layer.

16. A method for sealing an electronic device, the method comprising:
securing, by a sealing layer, a frame with a housing, the sealing layer comprising a liquid-activated particle; and
when the liquid-activated particle is exposed to a liquid:
absorbing, by the liquid-activated particle, at least some of the liquid, and
expanding, by the liquid-activated particle, from a first size to a second size greater than the first size.

17. The method of claim 16, wherein the liquid-activated particle comprises a spherical material that includes hydrophilic rubber.

18. The method of claim 16, further comprising adhering, by the liquid-activated particle, to at least one of the housing or the frame.

19. The method of claim 16, embedding a second sealing layer within the frame, the second sealing layer comprising a second liquid-activated particle.

20. The method of claim 16, wherein the sealing layer comprises:
a first adhesive section;
a second adhesive section; and
a third adhesive section that separates the first adhesive section from the second adhesive section, wherein the liquid-activated particle is located in the third adhesive section.
